(19) United States
(12) Patent Application Publication
(10) Pub. No.: US 2006/0186442 A1
(43) Pub. Date: Aug. 24, 2006

(54) Image sensor and method for fabricating the same

(75) Inventor: Hyun-Pil Noh, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/329,489

(22) Filed: Jan. 11, 2006

(30) Foreign Application Priority Data
Feb. 24, 2005 (KR) 10-2005-15492

(51) Int. Cl. H01L 31/113

(52) U.S. Cl. 257/292

(57) ABSTRACT

An image sensor and a method for fabricating the image sensor are provided. The image sensor includes a doped layer of a first conductivity type formed in a photodiode region defined in a semiconductor substrate, a first epitaxial layer of a second conductivity type and a second epitaxial layer of the second conductivity type formed on the semiconductor substrate in which the doped layer has been formed. Moreover, the first epitaxial layer has a bandgap energy different from that of the second epitaxial layer.

### CROSS-REFERENCE TO RELATED APPLICATION

This application claims priority from Korean Patent Application No. 10-2005-15492, filed Feb. 24, 2005, the disclosure of which is hereby incorporated by reference in its entirety.

### BACKGROUND OF THE INVENTION

1. Field of the Invention

The present invention relates to a semiconductor device and a method for fabricating the same, and more particularly, to an image sensor and a method for fabricating the same.

2. Description of the Related Art

An image sensor is a device that converts an optical image into an electrical signal. An image sensor typically includes a pixel array, wherein a plurality of pixels are arranged in a two-dimensional matrix. Each of the pixels of the image sensor includes a photosensitive unit, a signal-transmitting unit, and a signal readout unit. The image sensor may be classified into a charge coupled device (CCD) type and a complementary metal oxide semiconductor (CMOS) type depending upon the structures of the signal transmitting unit and the signal readout unit. It is noted that a CCD type image sensor is typically superior in performance with respect to noise and photosensitivity quality in comparison to a CMOS type image sensor. However, with respect to integration and power consumption, a CCD type image sensor generally has a lower quality of performance in these areas in comparison to a CMOS type image sensor. Moreover, due to the increasing demand for highly-integrated and low-power consumption image sensors, development of the CMOS type image sensor is currently being accelerated.

FIG. 1 is a sectional view illustrating a method for fabricating a conventional image sensor.

Referring to FIG. 1, a photodiode 21 is made of a junction of an N-type doped layer 11 and a P-type doped layer 13. The photodiode 21 is formed in a given region on a semiconductor substrate 10. A transfer gate 23 having a conductive layer 17 formed on a gate insulating layer 16 is formed on an active region adjacent to the photodiode 21. In addition, a spacer structure 19 is formed on the sidewalls of the transfer gate 23. Moreover, a floating diffusion layer 15 is formed on a region opposite to the given region on which the photodiode 21 is formed. The photodiode 21 receives external light and generates the external light into a signal charge. The generated signal charge is then transmitted to the floating diffusion layer 15, and is then subsequently converted into an output voltage.

However, one of the difficulties with conventional image sensors is that generally the distance between the N-type doped layer 11 and a channel region is too far. The reason that the distance is generally too far is because the photodiode is typically made of a junction of a P-type doped layer and a N-type doped layer. As a result of the distance between the N-type doped layer 11 and channel region being too far from one another, the photodiode converts external light into the signal charge at a slow rate. Accordingly, there is a need for a method for improving the low photosensitivity of an image sensor.

### SUMMARY OF THE INVENTION

In an exemplary embodiment of the present invention, an image sensor is provided. The image sensor includes a doped layer of a first conductivity type formed in a photodiode region defined in a semiconductor substrate, a first epitaxial layer of a second conductivity type and a second epitaxial layer of the second conductivity type formed on the semiconductor substrate in which the doped layer has been formed. The first epitaxial layer has a bandgap energy different from that of the second epitaxial layer.

In another exemplary embodiment of the invention, a method for fabricating an image sensor is provided. The method includes forming a doped layer of a first conductivity type in a photodiode region defined in a semiconductor substrate and forming a first epitaxial layer of a second conductivity type and a second epitaxial layer of the second conductivity type on the semiconductor substrate in which the doped layer has been formed. The first epitaxial layer has an band gap energy different from that of the second epitaxial layer.

In another exemplary embodiment of the present invention, a method for fabricating an image sensor is provided. The method includes forming a first epitaxial layer and a second epitaxial layer on a semiconductor substrate in which a photodiode region is defined. The first epitaxial layer has an bandgap energy different from that of the second epitaxial layer. The method further includes forming a doped layer of a first conductivity type under the first epitaxial layer and implanting a dopant of a second conductivity type into the first epitaxial layer and the second epitaxial layer.

### BRIEF DESCRIPTION OF THE DRAWINGS

FIG. 1 is a sectional view illustrating a method for fabricating a conventional image sensor;

FIGS. 2A through 2E are sectional views illustrating a method for fabricating an image sensor according to an exemplary embodiment of the present invention;

FIG. 3 is a sectional view illustrating a method for fabricating an image sensor according to an exemplary embodiment of the present invention; and

FIGS. 4A through 4D are sectional views illustrating a method for fabricating an image sensor according to an exemplary embodiment of the present invention.

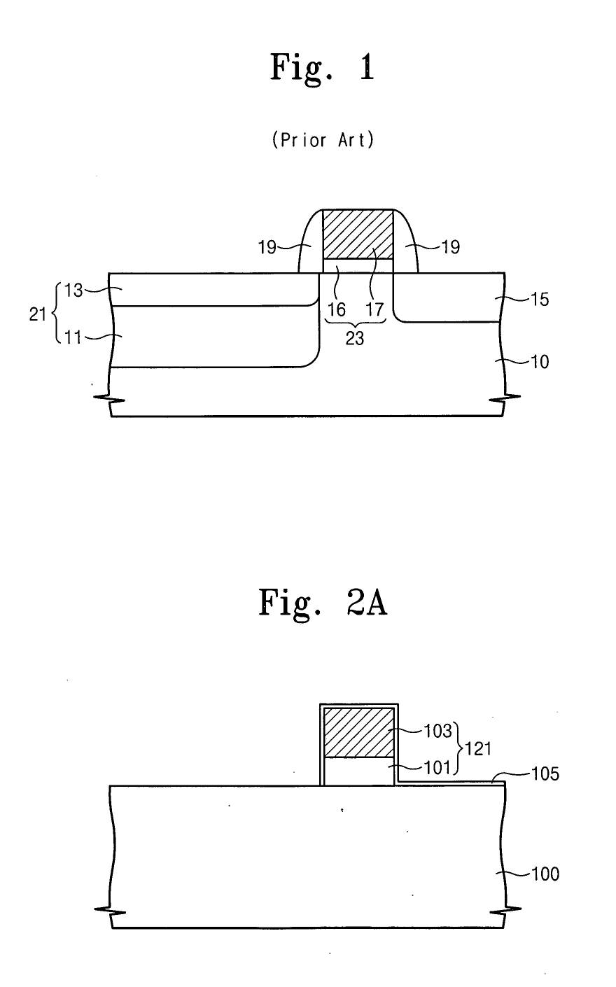

### DETAILED DESCRIPTION OF THE EXEMPLARY EMBODIMENTS OF THE INVENTION

Reference will now be made in detail to the preferred embodiments of the present invention, examples of which are illustrated in the accompanying drawings. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their detailed description will be omitted for conciseness.

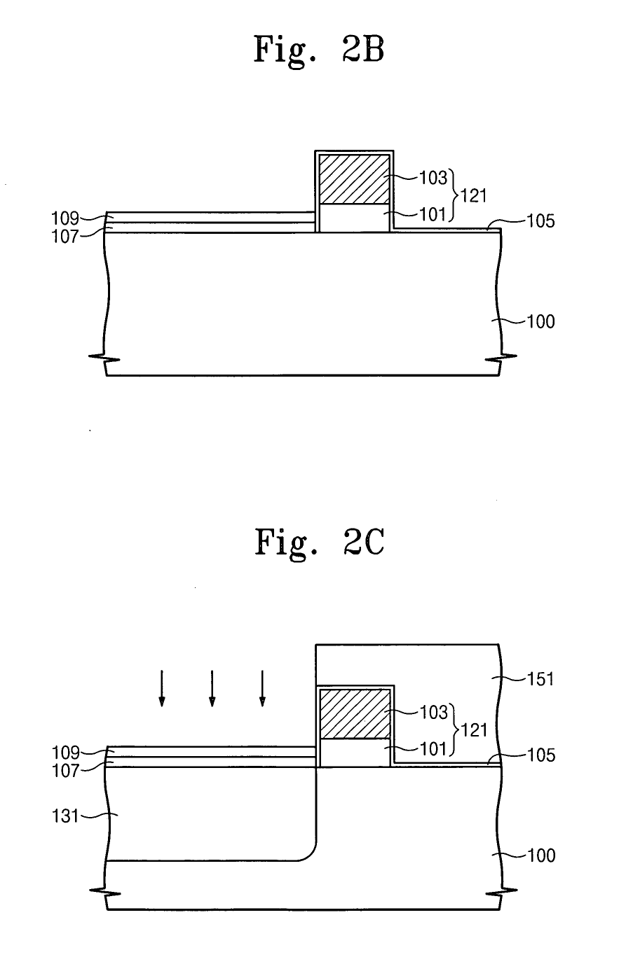

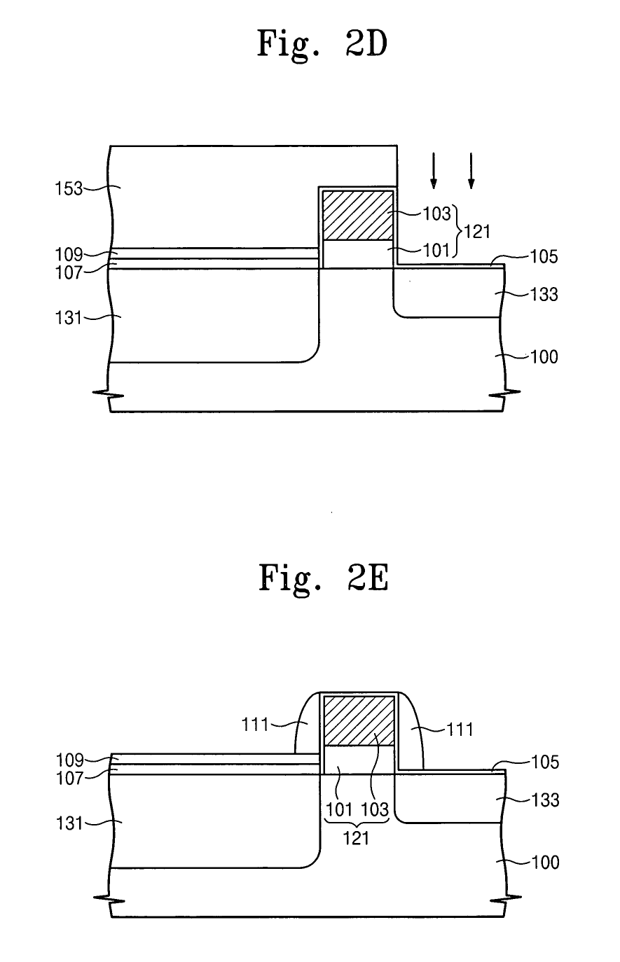

FIGS. 2A through 2E are sectional views illustrating a method for fabricating an image sensor according to an exemplary embodiment of the present invention.

Referring to FIG. 2A, a gate insulating layer 101 and a conductive layer 103 are sequentially deposited on a semiconductor substrate 100 and are then patterned to form a transfer gate 121. Moreover, the semiconductor substrate 100 may be formed by depositing a P-type or N-type epitaxial layer on a silicon (Si) semiconductor substrate. Also, a deep P well may be additionally formed in a boundary region between the silicon semiconductor substrate and the P-type or N-type epitaxial layer by doping a dopant ion into the P-type or N-type epitaxial layer.

Thereafter, a reaction-barrier layer 105 is deposited on the resulting structure. A portion of the reaction-barrier layer 105, which has been formed on a photodiode region, is removed by a patterning process. The remaining reaction-barrier layer 105 causes an epitaxial layer to be formed only on the photodiode region in a subsequent process. Accordingly, the reaction-barrier layer 105 is formed of a material (preferably, an oxide) that can prevent the growth of the epitaxial layer on a region other than the photodiode region. The reaction-barrier layer 105 serves as a buffer layer in a subsequent ion-implantation process.

Referring to FIG. 2B, a silicon germanium (SiGe) epitaxial layer 107 and a silicon (Si) epitaxial layer 109 are sequentially formed in the photodiode region on the semiconductor substrate 100. Germanium (Ge) has a band gap (0.66 eV) lower than the band gap (1.12 eV) of silicon (Si). Accordingly, when the SiGe epitaxial layer 107 is formed on the photodiode region, the amount of generated charge is increased to improve the photosensitivity of the image sensor.

Referring to FIG. 2C, a photoresist pattern 151 is formed on a region other than the photodiode region, and an N-type doped layer 131 is formed in the photodiode region through an ion-implantation process. A P-type dopant ion is implanted into the Si epitaxial layer 109 and the SiGe epitaxial layer 107 to form a photodiode junctioned to the N-type doped layer 131. The photoresist pattern 151 is then removed. In contrast to a conventional image sensor in which a P-type doped layer constituting a photodiode is formed in a semiconductor substrate, the image sensor of the exemplary embodiments of the present invention has a P-type doped layer formed higher than a channel. Accordingly, the length between the N-type doped layer and the channel is reduced, thereby increasing the output speed of a signal charge.

Moreover, in the present exemplary embodiment depicted in FIG. 2C, an N-type dopant ion may be implanted to form an N-type doped layer prior to forming the SiGe epitaxial layer 107 and the Si epitaxial layer 109 in the photodiode region. The SiGe epitaxial layer 107 of a P-type conductivity and the Si epitaxial layer 109 of the P-type conductivity may be formed by an in-situ doping process.

Referring to FIG. 2D, a photoresist pattern 153 is formed to cover the photodiode region, and then a floating diffusion layer 133 is formed by an ion-implantation process. The photoresist pattern 153 is then removed. A signal charge generated in the photodiode region is transmitted to the floating diffusion layer 133, and is then converted into an output voltage by a drive transistor and a row select transistor.

Referring to FIG. 2E, a nitride layer with an uniform thickness is deposited on the resulting structure and is then overall etched, thereby forming a spacer structure 111 on sidewalls of the transfer gate 121.

As described above, in contrast to the conventional method of forming a photodiode consisting of a P-type doped layer and an N-type doped layer in a semiconductor substrate, the method of the exemplary embodiments of the present invention forms a P-type doped layer to be higher than a channel. As a result, with the methods of the present exemplary embodiments, the length between the N-type doped layer and the channel is reduced, thereby increasing the output speed of a signal charge. In addition, the amount of generated charge is increased due to the low band gap energy of the SiGe epitaxial layer formed on the photodiode region, thereby also improving the photosensitivity of the image sensor.

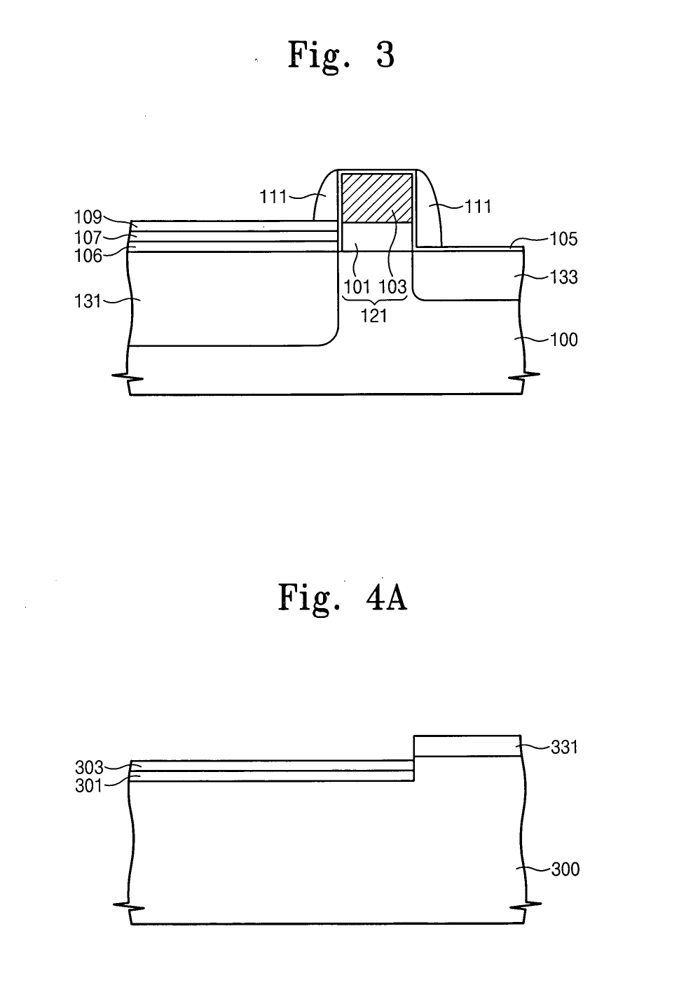

FIG. 3 is a sectional view illustrating a method for fabricating an image sensor according to an exemplary embodiment of the present invention.

The method illustrated in FIG. 3 is substantially the same as that in FIGS. 2A through 2E. A Si epitaxial layer 106 is additionally formed between the semiconductor substrate 100 and the SiGe epitaxial layer 107.

Referring to FIG. 3, after the N-type doped layer 131 is formed on the semiconductor substrate 100 by the ion-implantation process illustrated in FIG. 2C, a P-type dopant ion is implanted into all of the Si epitaxial layer 109, the SiGe epitaxial layer 107 and the Si epitaxial layer 106.

In general, Ge can generate a lot of electrons due to thermal excitation even at room temperature, and thus a dark current can be generated. Accordingly, the Si epitaxial layer 106 is additionally formed between the semiconductor substrate 100 and the SiGe epitaxial layer 107 so as to prevent thermal electrons excited in the SiGe epitaxial layer 107 from reaching the N-type doped layer 131. Alternatively, to prevent the generation of the dark current, a P-type dopant ion may be implanted below a given region of the semiconductor substrate 100, which is adjacent to the SiGe epitaxial layer 107, during the ion-implantation of the P-type dopant into the Si epitaxial layer 109 and the Si epitaxial layer 107, without additionally forming the Si epitaxial layer 106.

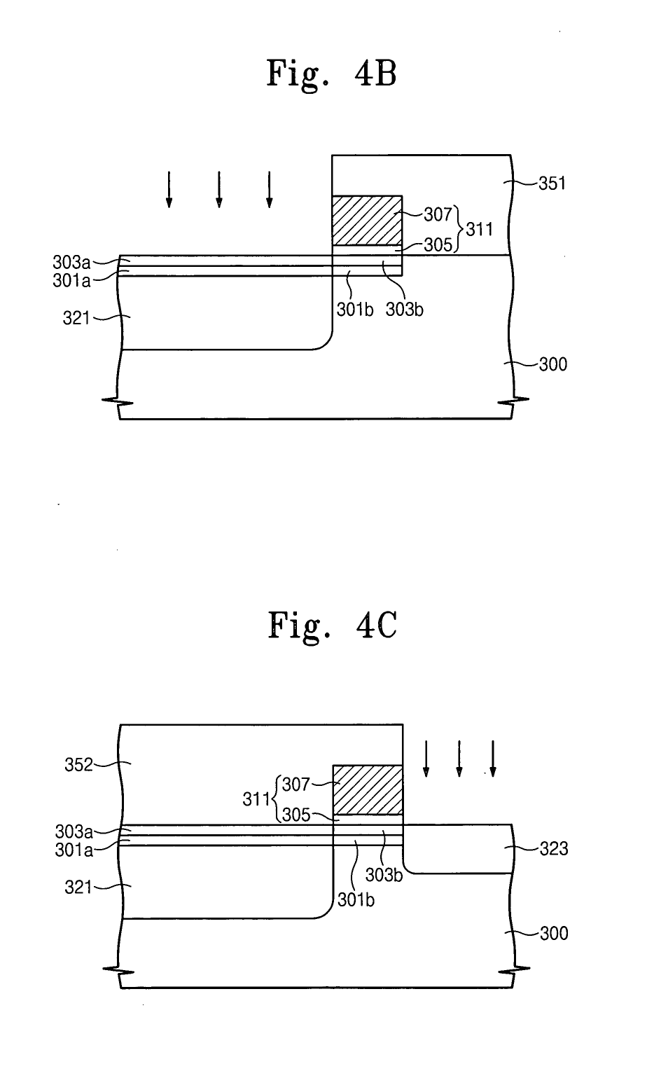

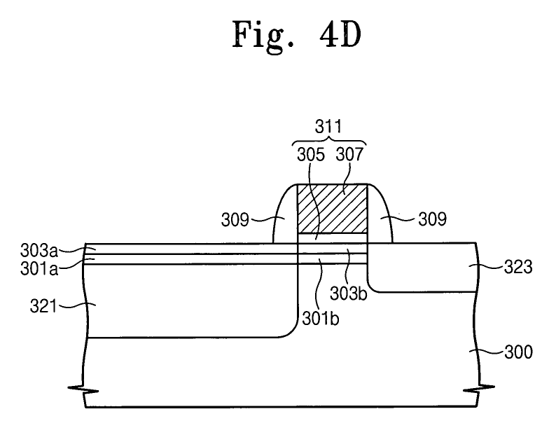

FIGS. 4A through 4D are sectional views illustrating a method for fabricating an image sensor according to an exemplary embodiment of the present invention.

Referring to FIG. 4A, a hard mask 331 is formed on a semiconductor substrate 300, and then a region on which a photodiode and a transfer gate are to be formed is etched. The hard mask 331 is used for etching the semiconductor substrate 300, and simultaneously serves to restrict a region on which an epitaxial layer is formed during a subsequent process. An SiGe epitaxial layer 301 and an Si epitaxial layer 303 are sequentially formed on the region where the photodiode and the transfer gate are to be formed. Next, the hard mask 331 is then removed. Thereafter, an ion-implantation process is performed for adjusting the threshold voltage of the transfer gate. Alternatively, the SiGe epitaxial layer 301 and the Si epitaxial layer 303 may be formed on the semiconductor substrate without performing the above etching process.

Referring to FIG. 4B, a gate insulating layer 305 and a conductive layer 307 are sequentially deposited on the semiconductor substrate 300 on which the SiGe epitaxial layer 301 and the Si epitaxial layer 303 have been formed, and are then patterned to form a transfer gate 311. Thereafter, a region other than a photodiode region is covered with a photoresist pattern 351, and then an N-type dopant ion is implanted to form an N-type doped layer 321. Next, a P-type dopant ion is implanted into the SiGe epitaxial layer 301 and the Si epitaxial layer 303 to form a photodiode. At this time, an ion-implantation process is performed at proper density and energy such that the P-type dopant is transmitted only to an SiGe epitaxial layer 301a and an Si epitaxial layer 303a that have been formed on the N-type doped layer 321, without being transmitted to an SiGe epitaxial layer 301b and an Si epitaxial layer 303b that have been formed below the transfer gate 311. Accordingly, the SiGe epitaxial layer 301b and the Si epitaxial layer 303b are used as a channel region for transmitting a signal charge from the photodiode to a floating diffusion layer 323 (see FIG. 4C).

Referring to FIG. 4C, the region on which the photodiode has been formed is covered with a photoresist pattern 352, and then the floating diffusion layer 323 is formed by an ion-implantation process. Thereafter, a spacer structure 309 is formed on sidewalls of the transfer gate 311 as illustrated in FIG. 4D.

As described above, the SiGe epitaxial layer having a lower band gap than the Si epitaxial layer is formed in the photodiode region, thereby enhancing the amount of the generated charge and the photosensitivity of the image sensor. Also, the SiGe epitaxial layer and the Si epitaxial layer are formed in the photodiode region on the semiconductor substrate and then the P-type dopant ion is implanted to form the photodiode, thereby increasing the transmission speed of the signal charge because the distance between the N-type doped layer and the channel is reduced due to the P-type doped layer being formed higher than the channel.

Having described the exemplary embodiments of the present invention, it is further noted that it is readily apparent to those reasonably skilled in the art that various modifications may be made without departing from the spirit and scope of the invention which is defined by the metes and bounds of the appended claims.

What is claimed is:

1. An image sensor comprising:
a doped layer of a first conductivity type formed in a photodiode region defined in a semiconductor substrate; and
a first epitaxial layer of a second conductivity type and a second epitaxial layer of the second conductivity type formed on the semiconductor substrate in which the doped layer has been formed, the first epitaxial layer having bandgap energy different from that of the second epitaxial layer.

2. The image sensor of claim 1, wherein the first epitaxial layer has a smaller band gap energy than the second epitaxial layer.

3. The image sensor of claim 1, further comprising a third epitaxial layer of the second conductivity type formed between the first epitaxial layer and the semiconductor substrate on which the doped layer has been formed, the third epitaxial layer having substantially the same bandgap energy as the second epitaxial layer.

4. The image sensor of claim 1, wherein the first epitaxial layer and the second epitaxial layer are formed on an upper surface of the doped layer.

5. The image sensor of claim 1, further comprising:
a floating diffusion layer formed in the semiconductor substrate, and spaced apart from the doped layer; and
a transfer gate formed between the doped layer and the floating diffusion layer on the semiconductor substrate,
wherein the transfer gate transmits a signal charge from the doped layer to the floating diffusion layer.

6. A method for fabricating an image sensor, the method comprising:
forming a doped layer of a first conductivity type in a photodiode region defined in a semiconductor substrate; and
forming a first epitaxial layer of a second conductivity type and a second epitaxial layer of the second conductivity type on the semiconductor substrate in which the doped layer has been formed, the first epitaxial layer having bandgap energy different from that of the second epitaxial layer.

7. The method of claim 6, wherein the forming of the doped layer, the first epitaxial layer and the second epitaxial layer comprises:
forming the first epitaxial layer and the second epitaxial layer on the semiconductor substrate in which the photodiode region is defined;
implanting a dopant ion of the first conductivity type to form the doped layer under the first epitaxial layer; and
implanting a dopant ion of the second conductivity type into the first epitaxial layer and the second epitaxial layer.

8. The method of claim 6, wherein the forming of the doped layer, the first epitaxial layer and the second epitaxial layer comprises:
forming the doped layer in the photodiode region by an ion-implantation process; and
forming the first epitaxial layer and the second epitaxial layer on the doped layer in an in-situ process.

9. The method of claim 7, further comprising before the forming of the first and second epitaxial layers:
depositing at least a portion of a reaction-barrier layer in the photodiode region; and
removing the portion of the reaction-barrier layer formed in the photodiode region.

10. The method of claim 6, further comprising forming a third epitaxial layer of the second conductivity type between the first epitaxial layer and the semiconductor substrate on which the doped layer has been formed, the third epitaxial layer having substantially the same bandgap energy as the second epitaxial layer.

11. A method for fabricating an image sensor, the method comprising:
forming a first epitaxial layer and a second epitaxial layer on a semiconductor substrate in which a photodiode region is defined, the first epitaxial layer having bandgap energy different from that of the second epitaxial layer;
forming a doped layer of a first conductivity type under the first epitaxial layer; and
implanting a dopant of a second conductivity type into the first epitaxial layer and the second epitaxial layer.

12. The image sensor of claim 1, wherein the first epitaxial layer is a silicon germanium (SiGe) epitaxial layer, the second epitaxial layer is a silicon (Si) epitaxial layer, and the doped layer is a N-type doped layer.

13. The image sensor of claim 3, wherein the first epitaxial layer is a silicon germanium (SiGe) epitaxial layer, the second epitaxial layer is a silicon (Si) epitaxial layer, the third epitaxial layer is a silicon (Si) epitaxial layer, and the doped layer is a N-type doped layer.

14. The method of claim 6, wherein the first epitaxial layer has a smaller band gap energy than the second epitaxial layer.

15. The method of claim 7, wherein an N-type dopant ion is implanted to form the doped layer under the first epitaxial layer, and a P-type dopant ion is implanted into the first epitaxial layer and the second epitaxial layer.

16. The method of claim 10, wherein the first epitaxial layer is a silicon germanium (SiGe) epitaxial layer, the second epitaxial layer is a silicon (Si) epitaxial layer, the third epitaxial layer is a silicon (Si) epitaxial layer, and the doped layer is a N-type doped layer.

17. The method of claim 16, wherein the forming of the doped layer, the first epitaxial layer, the second epitaxial layer and third epitaxial layer comprises:
implanting a N-type dopant ion to form the doped layer under the first epitaxial layer; and
implanting a P-type dopant ion into the first epitaxial layer, the second epitaxial layer and the third epitaxial layer.

18. The method of claim 11, wherein the first epitaxial layer has a smaller band gap energy than the second epitaxial layer.

19. The method of claim 11, wherein the first epitaxial layer is a silicon germanium (SiGe) epitaxial layer, the second epitaxial layer is a silicon (Si) epitaxial layer, and the doped layer is a N-type doped layer.

20. The method of claim 11, further comprising before the forming of the first and second epitaxial layers:
depositing at least a portion of a reaction-barrier layer in the photodiode region; and
removing the portion of the reaction-barrier layer formed in the photodiode region.
